(19) United States
(12) Patent Application Publication
(10) Pub. No.: US 2012/0034727 A1
(43) Pub. Date: Feb. 9, 2012

(54) MULTILAYERED PHOTOVOLTAIC DEVICE ON ENVELOPE SURFACE

(75) Inventors: Igor Lvovich SKRYABIN, Yarralumla (AU); George PHANI, Illawong (AU); Sylvia Medlyn TULLOCH, Burra Creek (AU); Graeme Leslie EVANS, Kambah (AU); Ben JAUSNIK, Griffith (AU)

(73) Assignee: DYESOL INDUSTRIES PTY LTD, Queanbeyan NSW (AU)

(21) Appl. No.: 13/164,231

(22) Filed: Jun. 20, 2011

Related U.S. Application Data
(62) Division of application No. 10/577,971, filed on Jul. 14, 2009, now abandoned.

(30) Foreign Application Priority Data
Nov. 3, 2003 (AU) 2003906026
Nov. 19, 2003 (AU) 2003906361
Jun. 24, 2004 (AU) 2004903440
Sep. 24, 2004 (AU) 2004905662

(51) Int. Cl. H01L 31/18

(52) U.S. Cl. 438/64; 257/E31.001

(57) ABSTRACT

A method of producing a dye solar cell photovoltaic device. The method comprises the steps of providing a transparent envelope, with at least a portion of the envelope having a curved profile; and forming a dye solar cell voltaic element by depositing a plurality of layers of film on an inside surface of the envelope and thereby defining a space within the photovoltaic element.

### TECHNICAL FIELD

This invention relates to the thin film photovoltaic devices and sensors, materials and methods used for electrical connections for such devices, in particular, to materials and methods used for fabrication of such devices.

More particularly this invention relates to the nano-particulate photo-electrochemical (PEC) devices including sensors and photovoltaic cells. Examples of the nano-particulate PEC devices are disclosed in the following patents and applications:

U.S. Pat. No. 4,927,721, Photoelectrochemical cell; Michael Graetzel and Paul Liska, 1990.

U.S. Pat. No. 5,525,440, Method of manufacture of photo-electrochemical cell and a cell made by this method; Andreas Kay, Michael Graetzel and Brian O'Regan, 1996.

U.S. Pat. No. 6,297,900, Electrophotochromic smart window; Gavin Tulloch and Igor Skryabin, 2001.

PCT/AU01/01354, UV sensors and arrays and methods to manufacture thereof, George Phani and Igor Skryabin.

Further the invention relates to application of such devices for powering small wireless sensors, also known as motes or smart dust.

BACKGROUND TO THE INVENTION

PEC cells, as of the type disclosed in the above patents belong to the broader class of thin film multilayer photovoltaic (PV) devices.

These devices are fabricated in a planar laminate arrangement either between two large area substrates or on a single substrate. One typical arrangement involves two glass substrates, each utilising an electrically conducting coating upon the internal surface of each substrate. Another, typical arrangement involves the first substrate being glass or polymeric and utilising an electrically conducting coating upon the internal surface of the substrate, with the second substrate being polymeric. In some arrangements, the internal surface of said second polymeric substrate is coated with an electrically conducting coating, whereas in other arrangements, said second polymeric substrate comprises a polymeric foil laminate, utilising adjacent electrically conductive material, such as carbon. Also, in some arrangements, the external surface may be a laminated metal film, and in other arrangements, the external surface may be coated by a metal. At least one of said first and second substrates is substantially transparent to visible light, as is the attached transparent electrically conducting (TEC) coating.

PEC cells contain a photoanode, typically comprising a dye-sensitised, nanoporous semiconducting oxide (eg. titanium dioxide or titania) layer attached to one conductive coating, and a cathode, typically comprising a redox electrocatalyst layer attached to the other conductive coating or conductive material. An electrolyte containing a redox mediator is located between the photoanode and cathode; the electrolyte is sealed from the environment.

TEC coatings, which usually comprise a metal oxide(s), have high resistivity when compared with normal metal conductors, resulting in high resistive losses for large area PEC cells operating under high illumination.

One example of the manufacture of a PEC module involves the use of, two glass substrates that have TEC-coatings that have been divided into electrically isolated regions. Titanium dioxide (or similar semiconductor) is screen printed onto selected areas of the TEC coating of one substrate and a catalyst is screen printed onto selected areas of the TEC coating of the other substrate. The titanium dioxide is coated with a thin layer of a dye by immersion of the titania-coated substrate in the dye solution. Strips of sealant and interconnect material are deposited upon one of the substrates and the two substrates are then bonded together. Electrolyte is added to the cells via access apertures in one of the substrates and these apertures are then sealed.

Another example of the manufacture of a PEC module involves the use of one substrate with a TEC-coating that has been divided, into electrically isolated regions. Successive layers of titania, insulating ceramic oxide, and conducting catalytic material (for example, carbon-based) are deposited, for example by screen printing, onto selected areas of the TEC-coated substrate, with the catalytic layer also serving as an interconnect. The titania is coated with a thin layer of the dye by immersion of the multiple-coated substrate in the dye solution. Electrolyte is added to the spaces within the porous titania-insulator-catalytic layers. The sealant face of a sealant/polymer and/or metal foil laminate is sealed to the substrate.

One advantage of PEC devices described above is in better than of conventional sold state device angular performance. It has been demonstrated that these devices perform well even under diffuse light conditions or when solar angle of incidence differs from normal. This advantage is attributed to nano-particultate structure of photo-active layers, that provides high area of photoactive surface. Each nano-particle, coated with thin layer of dye absorbs light incident from all directions, thus improving angular performance for a whole cell.

Unfortunately, these advantages of PEC are not fully utilized in the planar substrates. An interface between a planar substrate and air reflects significant part of solar energy, especially at high angles of incidence. Antireflective coatings could overcome this problem only partially; their antireflective properties are typically wavelength dependent, thus optimized for only small part of solar spectra.

Further, the said PEC devices, especially of large size require highly conductive and optically transparent coating. Electrical resistance of transparent electrical conductors is often a limiting factor for performance of devices larger than 5-10 mm.

Also, it is difficult to implement planar thin film PV devices for powering miniature wireless sensors (motes). It is recognized that motes will, provide universal connectivity between physical environment and internet. Although originally developed for defense, intelligence and security the motes are expected to be utilized in various fields including: inventory and warehouse control, structural integrity assessment for buildings and bridges, building automation, metering, home networking, industrial automation and agricultural monitoring.

A mote comprises the following elements:

1. sensor

2. data processor

3. transmitter

4. Receiver and

5. Power source: energy storage+PV element

While technologies for elements 1) to 4) present practically unrestricted capacity for miniaturization and independent wireless operations, a sustainable and renewable independent power source is a key to market acceptance and success of the motes.

Motes currently available are around 3 cm by 5 cm, and miniaturization is linked to the availability of micropower generation in situ. Further, existing motes are of awkward shapes, not deliverable in a typical defense theater.

There are examples of micropower sources based on electrochemical energy storage (batteries) and on a photovoltaic element for continuous charging of the battery. Energy requirement is the main limitation in designs of small motes.

In, addition, the motes and their photovoltaic elements are currently realized in substantially flat structures. This affects aerodynamic properties of these devices, their visibility and limits available power. The planar PV devices of the small size are not capable of capturing sufficient amount of light, especially under hazy, smoky, cloudy or indoor light conditions.

### OBJECTIVES OF THE INVENTION

It is therefore an object of the present invention to provide a thin film PV device, more particularly a PEC device with improved performance, especially under diffuse light conditions, that are typical for operations of motes.

It is further object of the present invention to provide a photovoltaic device suitable for powering motes and integratable with a mote within one rigid module.

### SUMMARY OF THE INVENTION

In broad terms the invention provides for utilization of curved surfaces for formation of layers of thin film photovoltaic elements, in particular—of PEC elements.

The term ‘curved’ is used in this specification to describe substantially non-planar surfaces. Typically the surface is curved prior to the formation of the photovoltaic element. The typical curved surface used in this invention is characterized by the radius of the curvature being below 50 mm, but preferably—less than 10 mm. The dimensions of the curved element are less than 30-50 mm, but preferably—less than 5-10 mm.

The curved PV element allows for better capturing of light from all directions and provides better footprint efficiency (efficiency calculated with respect to the footprint (or cross-sectional) area of the element).

It is essential that the curved surface is provided by an envelope. The envelope ensures mechanical integrity of the photovoltaic device and provides for encapsulation of the photovoltaic element.

The photovoltaic element comprises several layers. in one embodiment, the photovoltaic element comprises layers of titanium dioxide, ruthenium based dye, electrolyte with iodide based mediator and carbon or platinum based counterelectrode.

The layers of the photovoltaic element could be formed either within the envelope or on the envelope.

When the layers are formed within the envelope the envelope must be made of optically transparent material. The invention provides for utilization of transparent plastic materials as well as of glass. Conductive coating of a transparent conductor is attached to the envelope to ensure effective collection of electrical current. The, invention provides for utilization of transparent conducting oxides (indium tin oxide, fluorine doped tin oxide, etc.) or of a mesh made of conducting fiber, for example—metallic mesh (stainless steel, titanium, tungsten, nickel, etc.).

When the layers are formed on the envelope the envelope is not necessarily transparent. In this case, non-transparent conducting coating may be utilized for collection of electrical current.

The invention provides for wide range of shapes of the envelope.

In one embodiment the envelope forms a dome containing the photovoltaic element. It is preferable that the dome is substantially a hemisphere. Typically the dome is mounted on a substrate forming a base of the dome.

To ensure environmental protection the envelope encapsulates the photovoltaic device.

In one embodiment the envelope is spherical. It is understood that the encapsulating envelope need not be a regular geometrical sphere, but could be any convenient shape. It is beneficial, however, if the envelope is an aerodynamic shape.

In another embodiment the envelope is in the form of polyhedron. The thin film PV element is formed on a side of the polyhedron. The invention provides for further encapsulation of the polyhedron such as an external, shape created by the encapsulant is aerodynamic.

From one aspect of invention a photovoltaic device comprises spherical electrically conductive core, on which layers of the PV element are sequentially deposited. The top, electrically conductive layer comprises any of known transparent electrically conductive materials including, but not limited to

transparent conducting oxides

conducting polymers

mesh made of conducting fiber.

A transparent plastic or glass envelope is then formed around the photovoltaic element.

The invention provides for a channel to be made in the envelope to enable external electrical connection(s) to the device. In one embodiment the conducting coating is extended to line all or part of the internal surfaces of said channel to provide the external electrical connection(s). In another embodiment the channel is filled with an electrically conductive material or non-conducting material (e.g. ceramic glaze), forming a bond with said conducting coating and sealing said hole(s).

At least one layer of the photovoltaic element comprises semiconductor. For wide band gap semiconducting materials invention provides for photo sensitization by dye, to absorb electromagnetic energy of light. It is preferable to utilize nano-dispersed semiconductors, thereby significantly increasing photoactive area of the element.

In one embodiment layers of the PV element are formed: on internal surface of a transparent spherical shape. The shape being made of glass, polymer or any other optically transparent material.

In another embodiment, the layers of PEC device are formed on the spherical electrically conductive core, the last layer being optically transparent. The said core is selected from metallic (Ti, W, SS, etc) or non-metallic (carbon, conductive polymers, etc.) conductors.

The invention provides for the photovoltaic device to be connected to a substrate by standard connecting means utilized in PCB technology. For the purpose of connection (both electrical and mechanical) the invention provides for electrically conductive pin, embedded into the envelope. In case of double sided PCB the invention provides for utilization of a hole in PCB for the back side connection.

The invention provides for using mirror-like plate or for deposition of highly reflective layer on top of the substrate.

It could be beneficial to place more than one photovoltaic devices on the same substrate and electrically interconnect them using grid of conductors. The invention also provides for a flexible supportive plate, when flexibility is required.

The invention further provides for using an internal space of a spherical device as an additional reservoir for electrolyte and drying agents. Additional electrolyte will extend useful life of the device.

The invention provides for the elements of a mote to be formed within a curved sealed envelope.

The envelope is commonly of a spherical type, however, it may be advantageous to implement other shapes, selected based on their aerodynamic properties and/or visibility.

According to one aspect of the invention, a thin film photovoltaic device is utilizing a surface of the envelope shape as a substrate.

In one embodiment, at least part, of the envelope is optically transparent and the said photovoltaic device is formed on internal surface of the envelope.

In another embodiment, the said photovoltaic device is formed on external surface of the envelope.

In further embodiment according to this aspect of the invention, some layers of the said thin film photovoltaic device are formed on internal surface of the said envelope, whereas other layers are formed on external surface of the envelope.

Although, this specification describes shape of the envelope as spherical, the invention is not limited to geometrical spheres, but provides for other, substantially curved and not necessary regular shapes and/or sections or partitions of the sphere.

The invention provides for envelopes to be made of glass, plastic, metals or any other suitable materials.

Although, the invention describes a photovoltaic element of thin film type, it is beneficial to utilize some specific thin film technologies such as organic PV (OPV), dye solar cells (DSC), Si, CdTe or ICS solar cells.

The invention provides for a hole to be made in the envelope to enable external electrical connection(s) to the device. In one example these connections are made to antenna required for transmission/reception of information.

In another embodiment the said antenna is formed on internal or external surface of the envelope by isolating regions of the said electrically conductive material into appropriate shapes.

In yet, another embodiment the antenna is a wire extended to outside of the envelope or attached to the external surface of the envelope.

According to another aspect of the invention the mote is formed inside a spherical glass envelope (glass globe). Internal surface of the globe is completely or partially coated by the transparent electronic conductor. Some regions of the transparent electronic conductor form a substrate for a thin film photovoltaic device.

Additionally an energy storage device is formed inside the envelope. The energy storage device is either a high capacity capacitor or an electrochemical battery or a combination thereof.

The invention provides for a thin energy storage device. The thin film energy storage device is commonly formed proximate to the thin film photovoltaic element. In some cases, however, the said thin energy storage device is formed on the separate part of internal or external surfaces of the envelope.

The said energy storage device and said photovoltaic element are electrically connected. It is found to be beneficial to place a diode in an electrical circuit between the energy storage device and the photovoltaic element. The invention provides for thin film diode formed between the photovoltaic element and the energy storage device. In some cases the layers of the said thin film diode cover substantially whole area of the photovoltaic element.

The invention also provides for conventional miniature energy storage device secured inside the envelope.

In addition, the data processing and data reception/transmission elements are secured inside the envelope and electrically connected to the energy storage device.

Position of the sensor in respect to the envelope depends on requirements of selected application.

For light sensing, the photovoltaic cell itself provides an electrical signal modulated in accordance with light intensity.

For some applications (such as chemical and biological monitoring) the sensor is extended outwardly of the envelope.

To protect from mechanical impact the envelope is additionally enclosed in a resilient cover (e.g. polyurethane).

To secure all the elements inside the envelope and provide mechanical rigidity a resilient material (plastic) being provided within the envelope.

For attaching to the various surfaces a layer of adhesive is created on the envelope.

The PV devices of this type can be precisely delivered to a target position by accelerating a device in a predetermined direction in such a way that after flying certain distance the device will be in contact with the target object and adhesive will provide for the device to remain in this position for a required length of time. The said acceleration may be given to a mote from a ground point or from the flying object (e.g. aircraft, helicopter).

Alternatively the PV device can be just dropped from a flying object. In this case height and speed of the flying object are taken into account to determine when to drop the mote in order for it to lend on predetermined surface.

The predetermined surface may belong to the moving ground object (e.g. car) or to a flying object.

In one embodiment the acceleration of a PV device is achieved in a device similar to the air rifle, where a pressure force of compressed air accelerate the mote to a certain speed in a certain direction. The direction and magnitude of speed are selected in such way that projectile of the flying PV device intersects surface of a target object.

From another aspect of the invention a photovoltaic device includes means for orienting the device.

In one embodiment, center of gravity of a device is shifted in such a way that under action of gravity force the device is oriented in a predefined direction. This orientation ensures the lowest position of center of gravity.

The self-oriented device ensures specific direction of the antenna (typically—upwards).

In another embodiment in accordance with this aspect of the invention, a mote additionally includes supporting means to ensure that the spherical body is positioned at a distance from the supporting surface.

The supporting means can include a rod or/and a spring projecting outwardly of the device. In one example, the supporting means include a foot. The foot may be coated with adhesive to ensure firm attachment to the supporting surface.

According to another aspect of the invention a device is oriented by aerodynamic forces that it experiences on flying pass. In one embodiment this is achieved by attaching small wings or a tail to the body of the device. In another embodiment a body is shaped in such a way, that wing-like geometry is created.

The invention provides for a rod to be made needle like (sharp), thus, when the rod hits the supporting surface, the needle penetrates into the surface, ensuring attaching the mote in a specific orientation.

The invention also provides for self-propelling means for delivery of a mote to a target surface. In one embodiment self-propelling is driven by chemical energy stored either inside a mote or in the attached small container. Part of the chemical energy remained after the self-propelling could be used to power the mote operations for a certain time.

A supporting surface that mote is attached to described in this specification could be horizontal, vertical or oblique.

### BRIEF DESCRIPTION OF DRAWINGS

Having broadly portrayed the nature of the present invention, embodiments thereof will now be described by way of example and illustration only. In the following description, reference will be made to the accompanying drawings in which:

FIG. 1 is an enlarged section of a multilayered PV device formed in accordance with first example (preferential embodiment) of the invention.

FIG. 2 is an enlarged section of a multilayered PV device formed in accordance with second example of the invention.

FIG. 3 is an enlarged section of a multilayered PV device formed in accordance with third example of the invention.

### DETAILED DESCRIPTION OF DRAWINGS

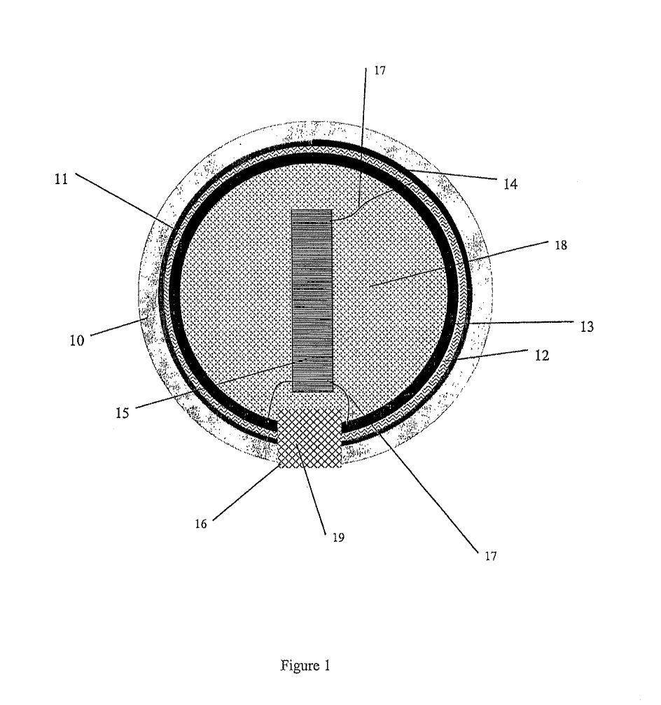

Referring to FIG. 1 a PV element is build inside a spherical envelope 10, on internal surface of which a thin film photovoltaic device 11, a diode 12 and an energy storage device 13 are subsequently formed. A part of the internal surface is allocated for the antenna 14. An electronic block 15 that comprises remaining subsystems of the mote is inserted into the sphere through an opening 16 and electrically connected to the energy storage element and to antenna using wires 17. The remaining space inside the sphere is filled with a filler 18 (good heat conductor) and the opening is blocked by a stopper 19.

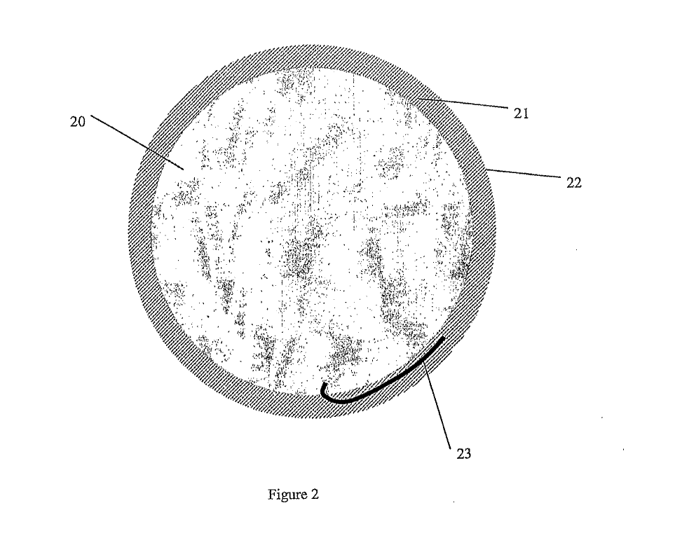

Referring to FIG. 2 a spherical envelope 20 is coated by a rubbery material 21, external surface 22 of which is made adhesive. An antenna 23 is extended from inside the envelope and secured in the rubbery layer.

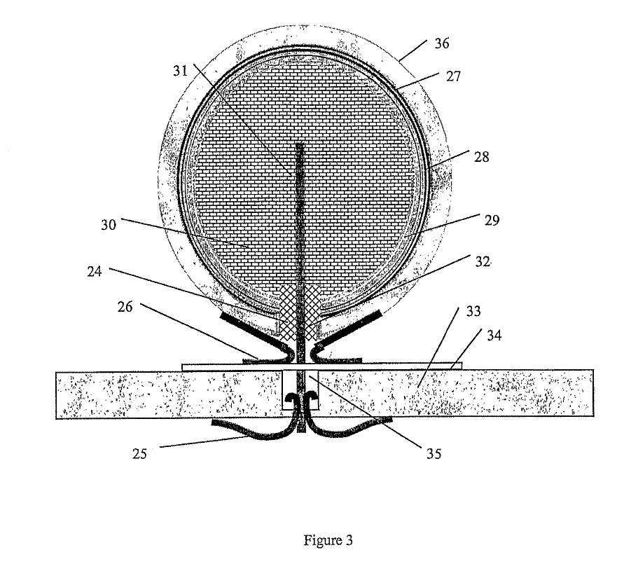

Referring to FIG. 3 a spherical PV device is formed on an internal surface of a hollow glass sphere 36. A hole 24 that is made in the sphere serves both for depositions of photovoltaic and energy storage layers and for connecting the device to spring loaded connectors 26. Subsequent layers of a transparent conductor 27, dye sensitised TiO₂ 28 and of a porous ceramic insulating material 29 (e.g. ZrO₂) are deposited on the internal surface of the sphere. The transparent conductor layer is extended to cover walls of the hole and a part of an external surface of the sphere. An electrolyte is added to the porous insulating material. After deposition of the layers' a space inside the sphere is filled with a carbon based material 30 that serves as a counter electrode for the PV element. A conductive pin 31 is secured in the carbon based material. Sealing 32 ensures that humidity and oxygen from environment could not penetrate inside the device. Additionally the sealing prevents evaporation of the electrolyte. The device is secured on a support 33 (flexible or rigid). Spring loaded connectors 25 and 26, ensure good electrical connections between the device and external electrical terminals located on both sides of the support. To enhance efficiency of the device a mirror 34 is placed underneath the device and on top of the support. A hole 35 made in the support provides for connection of the conductive pin 31 to the spring loaded connectors 25 placed on the bottom side of the support.

1-52. (canceled)

53. A method of producing a dye solar cell photovoltaic device, the method comprising the steps of:
providing a transparent envelope, with at least a portion of the envelope having a curved profile; and
forming a dye solar cell voltaic element by depositing a plurality of layers of film on an inside surface of the envelope and thereby defining a space within the photovoltaic element.

54. The method according to claim 53, further comprising the steps of forming a dome shape with the envelope; and
containing the device within the dome.

55. The method according to claim 54, further comprising the steps of mounting the dome on a substrate; and
forming a base of the dome with the substrate.

56. The method according to claim 53, further comprising the step of forming the curved shape profile of the envelope into a shape having a radius less than 30 mm.

57. The method according to claim 53, further comprising the steps mounting an electronic apparatus within the curved profile of the envelope;
electronically connecting the electronic apparatus to the photovoltaic element; and
arranging the photovoltaic element to provide electric power to the electronic apparatus.

58. The method according to claim 57, further comprising the steps of including a transmitter as part of the electronic apparatus for transmitting information.

59. The method according to claim 58, further comprising the steps of forming an antenna by a conductive region of the envelope; and
connecting the antenna to the transmitter.

60. The method according to claim 58, further comprising the steps of connecting an antenna to the transmitter;
including, as part of the antenna, a conductive member extending outwardly from the envelope.

61. The method according to claim 53, further comprising the step of providing an energy storage device.

62. The method according to claim 61, further comprising the step of forming at least one thin layer proximate the plurality of layers of film of the photovoltaic element, with the at least one thin layer functioning as the energy storage device.

63. The method according to claim 53, further comprising the step of providing a sensor.

64. The method according to claim 63, further comprising the step of extending the sensor outwardly from the envelope; and forming the curved profile of the envelope such that it has a radius of less than 10 mm.

65. The method according to claim 53, further comprising the steps of forming the photovoltaic device as a mote;
arranging the mote arranged to provide information about an environment.

66. The method according claim 65, further comprising the step of enclosing the photovoltaic device is enclosed with a resilient cover.

67. The method according to claim 65, further comprising the step of forming the outer shape of the photovoltaic device such that the outer shape is aerodynamic.

68. The method according to claim 65, further comprising the step of providing means for orienting the photovoltaic device.

69. The method according to claim 68, further comprising the step of selecting the orienting means such that the orienting means includes a predetermined center of gravity of the photovoltaic device.

70. The method according to claim 69, further comprising the step of selecting the orienting means such that the orienting means includes a projection projecting outwardly of the photovoltaic device.

71. The method according to claim 68, further comprising the step of selecting the orienting means such that the orienting means includes an adhesive portion on an outer surface of the photovoltaic device.

72. The method according to claim 53, further including the steps of mounting the device on a substrate; and
electrically connecting the device to the substrate.

73. A method of producing a dye solar cell photovoltaic device, the method comprising:
a element including a plurality of layers of film;
providing an envelope with at least a portion of the envelope having a curved profile;
forming a dye solar cell voltaic element on an inwardly facing surface of the envelope;
comprising the dye solar cell voltaic element out of a plurality of layers of film;
mounting the device on a substrate;
electrically connecting the device to the substrate;
forming a channel through the envelope to a conductive layer of the device and
connecting the conductive layer to the substrate via a conductor.

74. The method according to claim 73, further comprising the steps of including a grid of conductors in the substrate; and
electrically connecting the photovoltaic device to the grid.

75. The method according to claim 72, further comprising the steps of including a depression in the substrate, and mounting the photovoltaic device within the depression.

76. The method according to claim 72, further comprising the step of including reflective means as part of the substrate to reflect radiation incident on the substrate towards the photovoltaic device.

77. The method according to claim 53, further comprising the step of comprising an internal electrode of the voltaic element out of carbon; and
forming the envelope such that the curved profile has a radius of curvature of less than 5 mm.

78. The method according to claim 53, further comprising the steps of comprising storing a reservoir of electrolyte in the device; and providing an electrolyte supply from the reservoir of electrolyte to an electrolyte layer of the voltaic element.

79. The method according to claim 53, further including the step of providing a resilient material within the device to secure elements of the device and provide mechanical rigidity.

80. The method according to claim 53 and further comprising the step of accommodating one of an electronic block and a conductive pin within the space.
